(19) United States
(12) Patent Application Publication
(10) Pub. No.: US 2025/0079183 A1
(43) Pub. Date: Mar. 6, 2025

(54) CRYOGENIC PLASMA ETCHING USING C2H2F2

(71) Applicant: L'Air Liquide, Société Anonyme pour l'Etude et l'Exploitation des Procédés Georges Claude, Paris (FR)

(72) Inventors: Nathan STAFFORD, Newark, DE (US); Phong NGUYEN, Newark, DE (US); Colin JENNINGS, Newark, DE (US); Scott BILTEK, Newark, DE (US)

(21) Appl. No.: 18/239,037

(22) Filed: Aug. 28, 2023

(51) Int. Cl. H01L 21/3213; H01L 21/311

(52) U.S. Cl. CPC H01L 21/32139; H01L 21/31116; H01L 21/31144; H01L 21/32137

(57) ABSTRACT

A cryogenic etching method for forming an aperture by selectively etching one or more silicon-containing films in a substrate using a patterned mask layer deposited on top of the one or more silicon-containing films comprises mounting the substrate in a reaction chamber, cooling the substrate to a temperature below 25° C., introducing an etching gas C₂H₂F₂ into the reaction chamber, converting the etching gas to a plasma; and allowing an etching reaction to proceed between the plasma and the one or more silicon-containing films so that the one or more silicon-containing films are selectively etched versus the patterned mask layer to form the aperture.

### TECHNICAL FIELD

The present invention relates to a method of cryogenic plasma etching silicon-containing materials using a hydrofluorocarbon etching gas C₂H₂F₂ to manufacture semiconductor chips, such as 3D NAND flash and DRAM chip manufacturing.

### BACKGROUND

High aspect ratio plasma etch is very challenging. An emerging technology is use of very low substrate temperature, usually around −50° C. or lower, below traditional etch chamber limitations of −20° C. In this case much less polymerizing gases are needed thus speeding up the etch and allowing good profile control because the etch byproducts themselves act as sidewall protection. Thus, there is a need for new etchants to help solve such technical challenges under these conditions of low temperature etching.

Attempts for low temperature etching have been proceeded.

US 2023/0127467 discloses a process for low temperature etching that uses a HF gas, CₓF_{y} gas or CₛHₜFᵤ gas, and oxygen containing gas to etch SiN, and a second plasma step using a HF gas, CᵥF_{w} gas, and oxygen containing gas to etch SiO₂. The substrate is set to 0° C. or lower, in which the HF generating gas or HF species includes at least one of gas, radicals and ions of hydrogen fluoride. For example, at least one selected from the group consisting of CH₂F₂ gas, C₃H₂F₄ gas, C₃H₂F₆ gas, C₃H₃F₅ gas, C₄H₂F₆ gas, C₄H₅F₅ gas, C₄H₂F₆ gas, C₅H₂F₆ gas, C₅H₂F₁₀ gas, and C₅H₃F₇ gas, capable of generating HF species. The temperature is disclosed as less than 0° C., and as low as −70° C. or lower. CHF₃, C₄H₂F₆ and CH₂F₂ are listed as one of the CₛHₜFᵤ gases. In addition are disclosed the addition of phosphorous containing molecules such as PF₃, PCl₃, PF₅, PCl₅, POCl₃, PH₃, PBr₃, and PBr₅ to the etch. The phosphorus-containing gas may promote the adsorption of HF species in the plasma onto the surface of the substrate.

Kihara et al. (Beyond 10 um Depth Ultra-High speed Etch Process with 84% Lower Carbon Footprint for Memory Channel Hole of 3DNAND Flash over 400 layers, 2023 Symposium on VLSI Technology and Circuits Digest of Technical Papers) disclose an etching process utilizing an HF generating gas, in which HF is generated by CF₄/H₂ plasma, and the surface reaction rate between HF and SiO₂ increases rapidly at low temperatures resulting in high SiO₂ etching rate. HF species demonstrates great potential for high aspect ratio etching of dielectric material.

Dussart et al. discloses (Dussart et al., “Cryogenic Etching of Silicon Compounds Using a CHF₃ Based Plasma”, J. Applied Physics 133, 113306 (2023)), in which cryogenic etching of a-Si, SiO₂, and Si₃N₄ materials by CHF₃/Ar inductively coupled plasma is investigated in a range of temperature from −140 to +20° C. Samples of the three different materials are placed together on the same silicon carrier wafer. Depending on the experimental conditions, etching or deposition regimes are obtained on the samples. A process window between −120 and −80° C. is found in which the Si₃N₄ surface is etched while CFₓ deposition is obtained on a-Si and SiO₂ surfaces, resulting in an infinite etching selectivity of Si₃N₄ to other materials. At high enough self-bias (−120V) and very low temperature (<−130° C.), Si₃N₄ etch is reduced down to a very low value, while a-Si and SiO₂ are still being etched, which inverses the selectivity between Si₃N₄ and the two other materials. EDX analyses of a Si₃N₄/a-Si/SiO₂ layer stack after the same etching process carried out at 20 and −100° C. confirm the presence of carbon and fluorine on a-Si at low temperature, showing the effect of the low temperature to switch from the etching to deposition regime on this material.

U.S. Pat. No. 9,460,935 discloses method for fabricating semiconductor devices, in which C₂H₂F₂ is used for high aspect ratio etching. However, their disclosed temperature range is 25° C. to about 600° C., and in some embodiments, at a temperature of about 25° C. to about 200° C.

CN111154490 discloses a method of etching high aspect ratio container (HARC) and etching gases include C₂F₆, C₂HF₅, C₂H₂F₄, C₂H₃F₃, C₂H₄F₂, C₂H₅F, C₂F₄, C₂HF₃, C₂H₂F₂ and C₂H₃F. No temperature is disclosed.

WO2018182968 discloses methods and apparatus for etching a feature in a substrate, in which substrates may be etched using cryogenic temperatures and particular classes of reactants. In various examples, the substrate may be etched at a temperature of about −20° C. or lower, using a mixture of reactants that includes at least one reactant that is an iodine-containing fluorocarbon, an iodine-containing fluoride, a bromine-containing fluorocarbon, a sulfur-containing reactant, or one of another select set of reactants.

JP2001044173 discloses a plasma etching process using etching gases of a CₙHₙFₙ (where n>=2) such as a C₂H₂F₂ gas and a CₓH_{y}F_{z} gas (x<=3, x+y+z>=8) having a low C/F ratio, such as a C₂HF₅ gas, thereby control of selectivity can be realized by the C₂H₂F₂ gas, while control of the lack of etching by the CₓH_{y}F_{z} gas. A temperature, for example, in a range of −50° C. to 100° C. is maintained by appropriately adjusting the cooling refrigerant by a temperature controller.

U.S. Pat. No. 5,814,563 discloses a method for etching dielectrics but can be used to etch other films like TiN, in which C₂H₂F₂, an etchant like CF₄, N gas like NH₃, oxidizer like CO, including Ar for sputtering. NH₃ gas is capable of generating NH₃-containing species such as gases comprising NH₂−, NH₃, or NH₄+, ions or molecules, including for example NH₃, NH₄OH, CH₃NH₂, C₂H₅NH₂, C₃H₈NH₂, and mixtures thereof. The temperature of the substrate is maintained within about ±50° C.

KR19980085478 discloses contact hole formation method of semiconductor device, in which the contact hole is formed using the photoresist as a mask, C₄F₈ and C₃F₈ gas are used for a high selectivity etch. A process down to −40° C. and a use of C₂H₂F₂ to etch a photoresist mask material (typically deposited using spin on process) for forming a contact hole with plasma etch are disclosed.

U.S. Pat. No. 9,514,959 discloses etching gases such as C₄H₂F₆ used in a plasma etching process for high aspect ratio silicon material etching with substrate temperatures from −196° C. to 500° C.

Shin et al. (“SiO₂ Etching Characteristics of Perfluoro-2-butene (I-C₄F₈) and Hexafluoropropene (I-C₃F₆)”, Environmentally Benign Etching Technology Laboratory Association of Super-advanced Electronics Technologies 3-1 Morinosato Wakamiya, Atsugi-shi, 243-0198 JAPAN) discloses a comparison of etching properties of two isomers of C₄F₈ in which etching rate of SiO₂ and selectivity against materials such as PR, SiN and Si are different, which indicates the etching properties are associated to structures of the etching gases but not just the C:F ratio.

Ohiwa et al. (“SiO₂ Tapered Etching Employing Magnetron Discharge of Fluorocarbon Gas”, Jpn. J. Appl. Phys. Vol. 31 (1992) p 405-410) disclose an etching process down to −70° C. using CHF₃, in which SiO₂ etching rate drastically increases at temperatures below −20° C. even though there is higher deposition rate at lower temperatures. They also disclose that a large amount of volatile fluorocarbons are adsorbed on the film with decreasing temperature which enhances the polymer formation. These species evaporate with increasing temperature.

The conventional fluorocarbon and hydrofluorocarbon gases may have a high global warming potential (GWP), and also when exposed to a high power plasma they will break apart and potentially form species that also have high GWPs. These high GWP species are emitted. Table 1 includes the GWP values of commonly used etching gases in the semiconductor industry along with other molecules that may be plasma byproducts as well as other chemistries. As can be seen from the table the GWP of CF₄ (6630) and CHF₃ (12400) is extremely high. As such these molecules are detrimental to the issue of Global Warming. Other fluorocarbons or hydrofluorocarbons commonly used can include CH₂F₂, CH₃F, C₄F₈, C₄F₆, C₂F₆, C₃F₈, etc. Additionally, byproducts from the etch may include NO₂, CO, CO₂, COF₄, SiF₄, etc.

TABLE 1

| Gas | GWP₁₀₀ |
|---|---|
| CHF₃ | 12400 |
| C₂F₆ | 11100 |
| C₄F₈ | 9540 |
| CF₄ | 6630 |
| CH₂F₂ | 677 |
| NO₂ | 265 |
| C₄H₂F₆ | 4 |
| CO | 2.1 |
| CO₂ | 1 |
| COF₂ | <1 |
| CF₃I | <1 |
| C₄F₆ | <1 |
| C₂H₂F₂ | <1 |

In some instances these high GWP species may pass through a scrubbing device but these high GWP species have various efficiencies. Thus, there is a need for both low GWP etching gases that function in a cryogenic etching process window as well as gases that break down in the plasma and create low GWP byproducts.

### SUMMARY

Disclosed is a cryogenic etching method for forming an aperture by selectively etching one or more silicon-containing films in a substrate using a patterned mask layer deposited on top of the one or more silicon-containing films, the method comprising:
mounting the substrate in a reaction chamber;
cooling the substrate to a temperature below approximately 25° C.;
introducing an etching gas C₂H₂F₂ into the reaction chamber;
converting the etching gas to a plasma; and
allowing an etching reaction to proceed between the plasma and the one or more silicon-containing films so that the one or more silicon-containing films are selectively etched versus the patterned mask layer to form the aperture. The disclosed etching method may include one or more of the following features:
   further comprising adding one or more hydrofluorocarbon or fluorocarbon etching gases added to C₂H₂F₂ being selected from C₄F₆, C₄F₈, C₄H₂F₆, CHF₃, CH₂F₂, CH₃F, CF₄, C₂F₆, C₃F₈, SFr, NF₃, C₂F₄, C₃F₆, C₄F₁₀, C₅F₈, C₆F₆, C₁-C₆ CₓF_{y}H_{z} molecule (x, y, and z are integers), C₂H₅F, C₃H₇F, C₃H₂F₆, C₂HF₅, C₃H₂F₄, or combination thereof;
   further comprising adding an additive to C₂H₂F₂, wherein the additive is selected from H₂, SFr, NF₃, NH₃, Cl₂, BCl₃, BF₃, Br₂, F₂, FNO, FNO₃, HBr, HCl, HI, IF₅, IF₇, B₂He, HF, P containing gases selected from PF₃, PCl₃, PBr₃, PH₃, POCl₃, PF₅, POF₃, PH₃ or P(R)₃ where R is an alkyl, or fluorinated alkyl groups selected from CF₃;
   further comprising adding a co-reactant with the additive, wherein the co-reactant is selected from O₂, CO, CO₂, NO, NO₂, N₂O, SO₂, H₂S, COS, O₃, CₓO_{y}F_{z} (x, y and z are integers) selected from COF₂, C₂O₂F₂, CₓO_{y}F_{z}Hₘ (x, y, z and m are integers) selected from alcohol, ketone, acidic, ester type molecule selected from CF₃OH, CF₃OCF₃, (CF₃)₂C═O, CF₃COOH, or combinations thereof;
   further comprising adding a co-reactant with the additive, wherein the co-reactant is selected from O₂, CO, CO₂, NO, NO₂, N₂O, SO₂, H₂S, COS, O₃, CₓO_{y}F_{z} (x, y and z are integers), CₓO_{y}F_{z}Hₘ (x, y, z and m are integers), ester type molecule, or combinations thereof;
   the CₓO_{y}F_{z} (x, y and z are integers) being selected from COF₂, C₂O₂F₂;
   the CₓO_{y}F_{z}Hₘ (x, y, z and m are integers) being selected from alcohol, ketone, acidic;
   the ester type molecule being selected from CF₃OH, CF₃OCF₃, (CF₃)₂C═O, CF₃COOH;
   further comprising adding an inert gas to C₂H₂F₂, wherein the inert gas is selected from Ar, Kr, Xe, Ne, N₂, He or combination thereof;
   the etching gas C₂H₂F₂ being an isomer of C₂H₂F₂ with CAS No.: 75-38-7;
   the etching gas C₂H₂F₂ being an isomer of C₂H₂F₂ with CAS No.: 1630-78-0;
   the etching gas C₂H₂F₂ being an isomer of C₂H₂F₂ with CAS No.: 1630-77-9;
   the etching gas C₂H₂F₂ being an isomer of C₂H₂F₂ with CAS No.: 1691-13-0;
   the temperature being below approximately −50° C.;
   the temperature ranging from approximately −196° C. to approximately 300° C.;
   the temperature ranging from approximately −196° C. to approximately 60° C.;
   the temperature ranging from approximately −196° C. to approximately 25° C.;
   the temperature ranging from approximately −196° C. to approximately −50° C.;
   the one or more silicon-containing films comprising a layer of SiₐO_{b}H_{c}C_{d}Nₑ, where a>0, b, c, d and e≥0, selected from silicon oxide, silicon nitride, crystalline Si, poly-silicon, polycrystalline silicon, amorphous silicon, low-k SiCOH, SiOCN, SiC, SiON, or a layer of alternating silicon oxide and silicon nitride (ONON) films or alternating silicon oxide and poly-silicon (OPOP) films;
   the aspect ratio of the aperture ranging from 1:1 to 5:1;
   the aspect ratio of the aperture being above 1:1;
   the aspect ratio of the aperture being above 5:1;
   the aspect ratio of the aperture being above 10:1;
   the aspect ratio of the aperture being above 20:1;
   the aspect ratio of the aperture ranging from approximately 5:1 to approximately 500:1;
   an aspect ratio of the high aspect ratio aperture ranging from approximately 20:1 to approximately 400:1;
   an aspect ratio of the high aspect ratio aperture having an aspect ratio greater than 50:1;
   the aperture having a diameter ranging from approximately 0.1 nm to approximately 500 nm;
   the aperture having a diameter ranging from approximately 5 nm to approximately 500 nm;
   the aperture having a diameter less than 100 nm; and
   after the aperture is formed, the temperature of the substrate being increased to greater than −50° C.

### NOTATION AND NOMENCLATURE

The following detailed description and claims utilize a number of abbreviations, symbols, and terms, which are generally well known in the art, and include:

As used herein, the indefinite article “a” or “an” means one or more.

As used herein, “about” or “around” or “approximately” in the text or in a claim means±10% of the value stated.

As used herein, “room temperature” in the text or in a claim means from approximately 20° C. to approximately 25° C.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from previous manufacturing steps. For example, the wafers may include silicon layers (including, but not limited to, crystalline, amorphous, porous, etc.), silicon containing layers (including, but not limited to, SiO₂, SiN, SiON, SiCOH, etc.), metal or metal containing layers (including, but not limited to, copper, cobalt, ruthenium, tungsten, platinum, palladium, nickel, ruthenium, gold, etc.) or combinations thereof. Furthermore, the substrate may be planar or patterned. The substrate may be an organic patterned Iodinated carbon layer film. The substrate may include layers of oxides that are used as dielectric materials in field effect transistor (FET) such as FinFET, MOFSET, GAAFET (Gate all-around FET), Ribbon-FET, Nanosheet, Forksheet FET, Complementary FET (CFET), MEMS, 3D NAND, MIM, DRAM, or FeRam device applications (for example, ZrO₂ based materials, HfO₂ based materials, TiO₂ based materials, rare earth oxide based materials, ternary oxide based materials, etc.) or nitride-based films (for example, TaN, TiN, NbN) that are used as electrodes. The substrate may include layers of alternating oxides (e.g., SiO) and nitrides (e.g., SiN). One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates. The substrate may be any solid that has functional groups on its surface that are prone to react with the reactive head of a self-assembled monolayer (SAM), and may include without limitation 3D objects or powders.

The term “wafer” or “patterned wafer” refers to a wafer that has a stack of films on a substrate, at least the top-most film the stack of the films has topographic features or patterns that have been created in steps prior to etch and the patterned top-most film on is formed for pattern etch.

The term “processing” as used herein includes patterning, exposure, development, etching, deposition, cleaning, and/or removal of by-products, as required in forming a described structure.

The term of “deposit” or “deposition” refers to a series of processes where materials at atomic or molecular levels are deposited on a wafer surface or on a substrate from a gas state (vapor) to a solid state as a thin layer. Chemical reactions are involved in the process, which occur after creation of a plasma of the reacting gases or activation of the reacting gases by heat. The plasma may be capacitively coupled plasma (CCP), Inductively coupled plasma (ICP), electron cyclotron resonance (ECR) plasma, or a microwave plasma, but is not limited to. Suitable commercially available plasma etching chambers include but are not limited to the Lam Research Dual CCP reactive ion etcher Dielectric etch product family sold under the trademark Flex™ or the Tokyo Electron Tactras™ or Episode™ UL. The non-plasma exposure step may be performed in a different chamber than the plasma exposure step.

The term “aspect ratio” refers to a ratio of the height of a trench (or aperture) to the width of the trench (or the diameter of the aperture).

The term “high aspect ratio (HAR)” refers to an aspect ratio ranging from approximately 1:1 to approximately 500:1, preferably from approximately 20:1 to approximately 400:1.

The term “high aspect ratio etching” refers to the formation of a hole pattern in a target film by plasma etching method when aspect ratio of formed hole structures is exceeding value of 5.

Note that herein, the terms “film”, “layer” and “material” may be used interchangeably. It is understood that a film may correspond to, or related to a layer or a material, and that the layer may refer to the film and the material. Furthermore, one of ordinary skill in the art will recognize that the terms “film” or “layer” or “material” used herein refer to a thickness of some material laid on or spread over a surface and that the surface may range from as large as the entire wafer to as small as a trench or a line.

Note that herein, the terms “aperture”, “via”, “hole”, “trench” and “structure” may be used interchangeably to refer to an opening formed in a semiconductor structure.

As used herein, the abbreviation “NAND” refers to a “Negative AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

Note that herein, the terms “etch gas” and “etchant” may be used interchangeably when the etch gas is in a gaseous state at room temperature and ambient pressure. It is understood that an etch gas may correspond to, or be related to an etchant, and that the etchant may refer to the etch gas.

The terms “dope” or “doping” is used interchangeably to the process of incorporation of one or more elements into a film through various methods where that element may be chemically bond or physically bond, and the process of intentionally incorporating atoms of different elements into the film composition. The element(s) may be doped interstitial or substitutional within the film.

The standard abbreviations of the elements from the periodic table of elements are used herein. It should be understood that elements may be referred to by these abbreviation (e.g., Si refers to silicon, N refers to nitrogen, O refers to oxygen, C refers to carbon, H refers to hydrogen, F refers to fluorine, etc.).

The unique CAS registry numbers (i.e., “CAS”) assigned by the Chemical Abstract Service are provided to identify the specific molecules disclosed.

As used herein, the term “hydrofluorocarbon” refers to a saturated or unsaturated function group containing exclusively carbon, fluoride and hydrogen atoms.

As used herein, the term “fluorocarbon” refers to a saturated or unsaturated function group containing exclusively fluoride and hydrogen atoms.

As used herein, the term “GWP” refers to the Global Warming Potentials, typically on a 100 year timescale and comparing the global warming potential to CO₂.

As used herein, “CO₂ emission” or “CO₂ equivalent emission” refers to a comparison between C₂H₂F₂ and gases like CH₂F₂, a commonly used hydrofluorocarbon etching gas and the GWP of the emitted species from a plasma etch process.

Ranges may be expressed herein as from about one particular value, and/or to about another particular value. When such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

“Comprising” in a claim is an open transitional term that means the subsequently identified claim elements are a nonexclusive listing (i.e., anything else may be additionally included and remain within the scope of “comprising”). “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actors in the absence of express language in the claim to the contrary.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is a graph of the emission amounts of HF produced by C₂H₂F₂>CH₂F₂>C₄H₂F₆ in accordance with a comparison of Example 1;

FIG. 2 is a graph of the emission amounts of HF produced by C₂H₂F₂ and CH₂F₂ with N₂, respectively, in accordance with Example 2;

FIG. 3 is a graph of etching data comparison of C₂H₂F₂ and CH₂F₂ in accordance with Example 3;

FIG. 4 is a graph of deposition data comparison of C₂H₂F₂ and CH₂F₂ in accordance with Example 4; and

FIG. 5 is a graph of the emission amounts of HF and other byproduct species produced by C₂H₂F₂, CH₂F₂ and C₄H₂F₆ in accordance with Example 5.

### DESCRIPTION OF PREFERRED EMBODIMENTS

Disclosed are methods of cryogenic plasma etching silicon-containing materials using a hydrofluorocarbon etching gas C₂H₂F₂ to manufacture semiconductor chips, such as 3D NAND flash and DRAM chip manufacturing. Other applications could include plasma etch processes in logic etch, such as beck end of line (BEOL), or the like. Such high aspect ratio structures are very challenging to etch using conventional fluorocarbon and hydrofluorocarbon plasma etch methods, especially as new technology nodes are explored. The disclosed method of using the low temperature substrates may offer the opportunity to improve etching processes. Etching profile may be controlled at lower temperatures by limiting volatility byproducts to control etch profile to highly vertical features. For example, SiF₄ is volatile above −86° C.; CO₂ is volatile above −70° C.; and other etch byproducts may not be volatile at these temperatures.

In addition, the conventional fluorocarbon and hydrofluorocarbon gases may have a high global warming potential (GWP), and also when exposed to a high power plasma they break apart and potentially form species that also have high GWPs. These high GWP species are emitted. In some instances, these high GWP species may pass through a scrubbing device but these high GWP species have various efficiencies. C₂H₂F₂ is particularly attractive due to its very low GWP of <1 whereas other traditional fluorocarbon and hydrofluorocarbon etching gases have very high GWP, such as CH₂F₂ having a GWP of 677, as show in Table 1.

Here C₂H₂F₂ may be used as an HF or F generating gas and/or deposition gas in an etching chamber that contains low temperature substrates. The HF should be formed by a recombination of H and F in a plasma that should be directly related to the atomic concentration of an input gas into a chamber. The C₂H₂F₂ may act as both an HF source and a source of polymer to protect sidewalls of etched structures. The addition of phosphorous to etch recipes is known in increase etch rates potentially as a catalytic effect. Therefore, the addition of gases such as PF₃ or other P-containing gases to C₂H₂F₂ may serve to enhance the etching rates. Moreover, isomers of different hydrofluorocarbons and fluorocarbons have different species and different concentrations of species (see for example U.S. Pat. No. 9,514,959 shows mass spectra of two isomers of C₄H₂F₆ are different), which makes the amount of HF produced by a hydrofluorocarbon etching gas is not predictable.

C₂H₂F₂ has 4 primary isomers listed below in Table 2. Here the preferable C₂H₂F₂ molecule is CAS No.: 75-38-7.

TABLE 2

| | | | | Boiling |
|---|---|---|---|---|
| Name | Formula | Structure | CAS No. | Point |
| 1,1-difluoroethylene | C₂H₂F₂ | 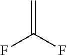 | 75-38-7 | −83° C. |
| (E)-1,2-difluoroethylene | C₂H₂F₂ | 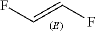 | 1630-78-0 | −86° C. |
| (Z)-1,2-difluoroethylene | C₂H₂F₂ | 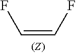 | 1630-77-9 | −36° C. |
| 1,2-difluoroethene | C₂H₂F₂ | 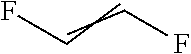 | 1691-13-0 | −28° C. |

C₂H₂F₂ is supplied in a gas cylinder at a variety of fill quantities, pressure and specifications. Preferably C₂H₂F₂ in the cylinder has a low moisture content of <40 ppm, preferably <10 ppm. C₂H₂F₂ may be purified to remove critical impurities such as other fluorocarbons, hydrofluorocarbons, chlorofluorocarbons (CFC's), impurities from air such as N₂, O₂, CO₂, moisture (H₂O), HF and other hydrocarbons such as CH₄, etc., using distillation, adsorption by molecular sieves, or other existing methods. Some impurities may form azeotropes, thus, other purification methods may need to be employed using chemical methods to separate them.

The disclosed cryogenic plasma etching method comprises exposing a substrate to an etching gas C₂H₂F₂ and/or one of its isomers, preferably C₂H₂F₂ CAS No.: 75-38-7, in a reaction chamber during an etching process and/or during a chamber conditioning process.

The disclosed cryogenic plasma etch method for forming an aperture by selectively etching one or more silicon-containing films in a substrate using a patterned mask layer deposited on top of the one or more silicon-containing films comprises:
mounting the substrate in a reaction chamber;
cooling the substrate to a temperature below 25° C.;
introducing an etching gas C₂H₂F₂ into the reaction chamber;
converting the etching gas to a plasma; and
allowing an etching reaction to proceed between the plasma and the one or more silicon-containing films so that the one or more silicon-containing films are selectively etched versus the patterned mask layer to form the aperture.

The reaction chamber may be any enclosure or chamber within a device in which etching methods take place, such as, without limitation, a reactive ion etching (RIE), a CCP with single or multiple frequency RF sources, an inductively coupled plasma (ICP), a microwave plasma reactors, or other types of etching systems capable of plasma processing, that is, selectively removing a portion of a dielectric film or generating active species or depositing films.

The reaction chamber is equipped with parallel plate electrodes plasma generators where a high frequency electromagnetic field of 60 MHz is applied to the upper electrode and a 2 MHz one is applied to the lower electrode, when the gap between the electrodes is kept in a range between 10 and 35 mm. Combination of these electric fields allows applying power to the upper electrode within a range of 0-2000 W and to the lower electrode within the range of 1500-7000 W. The plasma may be generated with a RF power ranging from about 25 W to about 100 kW. The plasma may be generated remotely or within the reaction chamber itself. RF frequency of the plasma may range from 100 KHz to 1 GHz. The plasma may be pulsed or continuous wave. In some embodiments, the power applied to the chamber may range from 0 to several kW of bias power and hundreds to several thousand kW of source power.

Temperature and pressure within the reaction chamber are held at conditions suitable for the processing films to react with the activated etching gas C₂H₂F₂. For instance, the pressure in the chamber may be held between approximately 0.1 mTorr and approximately 1000 Torr, preferably between approximately 1 mTorr and approximately 10 Torr, more preferably between approximately 10 mTorr and approximately 1 Torr, even more preferably between approximately 10 mTorr and approximately 100 mTorr, as required by etching parameters. Pressure in the etching chamber during the plasma-etching process may be maintained between 15 and 30 mTorr with introduced the process gas mixture. Likewise, substrate temperature in the reaction chamber may be <25° C., preferably <−50° C. Alternatively, the substrate temperature in the reaction chamber may range from approximately −196° C. to approximately 300° C.; preferably from approximately −196° C. to approximately 60° C.; more preferably from approximately −196° C. to approximately 25° C.; even more from approximately −196° C. to approximately −50° C. The substrates may be cooled by a variety of sources including commercially available chillers or other methods such as liquid N₂. Reaction chamber wall temperature may be <25° C., preferably <−50° C. The reaction chamber wall temperature may range from approximately −196° C. to approximately 25° C. depending on process requirements.

Reaction chamber wall temperature may be around >20° C., preferably <50° C. The reaction chamber wall temperature may be around room temperature or larger but less than 50° C. depending on process requirements.

Additional one or more hydrofluorocarbon or fluorocarbon etching gases may be added to C₂H₂F₂. The additional one or more hydrofluorocarbon or fluorocarbon etching gases may be selected from C₄F₆, C₄F₈, C₄H₂F₆, CH₂F₂, CH₃F, CHF₃, CF₄, C₂F₆, C₃F₈, SFr, NF₃, C₂F₄, C₃F₆, C₄F₁₀, C₅F₈, C₆F₆, C₁-C₆ CₓF_{y}H_{z} molecule (x, y and z are integers), C₂H₅F, C₃H₇F, C₃H₂F₆, C₂HF₅, C₃H₂F₄ or combination thereof.

Referring to Table 1, some hydrofluorocarbons or fluorocarbons have high GWP comparing to that of C₂H₂F₂. In order to enhance the etching performance and etching quality, one or more hydrofluorocarbon or fluorocarbon etching gases may be added to C₂H₂F₂ to slightly tune the etching performance. When a little amount of hydrofluorocarbons or fluorocarbons with high GWP values is added, the overall CO₂ equivalent emission from the reaction chamber may not impact a lot considering the improved etching performance. For example, less than 10% of one or more hydrofluorocarbon or fluorocarbon etching gases versus C₂H₂F₂ is added to C₂H₂F₂, the CO₂ equivalent emission from the reaction chamber may not change significantly comparing to the significantly improved etching performance. In reality, reducing the CO₂ equivalent emission and high etching performance may need to be balanced.

Other gases, such as additives, may be added to C₂H₂F₂. The additives include H₂, SFr, NF₃, N₂, NH₃, Cl₂, BCl₃, BF₃, Br₂, F₂, FNO, FNO₃, HBr, HCl, HI, IF₅, IF₇, HF, B₂H₆, and P-containing gases such as PF₃, PCl₃, PBr₃, PH₃, POCl₃, PF₅, POF₃, PH₃ and P(R)₃ where R is an alkyl or fluorinated alkyl group such as CF₃, or the like.

An inert gas may also be added to C₂H₂F₂. The inert gas is selected from Ar, Kr, Xe, Ne, N₂, He or combination thereof.

The disclosed cryogenic plasma etching method further comprises, prior to activating a plasma, sequentially or simultaneously exposing the substrate to a co-reactant with or without an additive, wherein the co-reactant is selected from O₂, CO, CO₂, NO, NO₂, N₂O, SO₂, H₂S, or COS, O₃, CₓO_{y}F_{z} (x, y and z are integers) such as COF₂, C₂O₂F₂, CₓO_{y}F_{z}Hₘ (x, y, z and m are integers) such as alcohol, ketone, acidic, ester type molecule such as CF₃OH, CF₃OCF₃, (CF₃)₂C═O, CF₃COOH, or combinations thereof.

The substrate contains silicon-containing materials, such as SiO₂, SiN, or Si. One example is alternating layers of SiO and SiN as used in 3D NAND applications. The silicon-containing film or material comprises a layer of SiₐO_{b}H_{c}C_{d}Nₑ, where a>0, b, c, d and e>0, selected from silicon oxide, silicon nitride, crystalline Si, poly-silicon, polycrystalline silicon, amorphous silicon, low-k SiCOH, SiOCN, SiC, SiON, or a stack of alternating silicon oxide and silicon nitride (ONON) films or alternating silicon oxide and poly-silicon (OPOP) films.

On top of the silicon-containing films or materials is a mask layer or mask material. The mask material may be a layer of amorphous carbon, doped amorphous carbon, spin on carbon (SOC), Si, SiN, Al, AlO, Ti, TiO or other metal and metal oxide masks, or other nitrides such as TiN, with or without dopants.

C₂H₂F₂ is supplied in a gas cylinder at a variety of fill quantities, pressure and specifications. Preferably the material has a low moisture content of <40 ppm, preferably <10 ppm. C₂H₂F₂ may be purified to remove critical impurities such as chlorine-species or organochlorides, other fluorocarbons, hydrofluorocarbons, chlorofluorocarbons (CFC's), impurities from the air (N₂, O₂, CO₂), moisture (H₂O), HF other hydrocarbons (CH₄, etc.), using distillation, adsorption using molecular sieves, or other commonly known methods in the art. Some impurities may form azeotropes thus other purification methods may need to be employed using chemical means to separate them.

After etching, the substrate may be warmed up to >−50° C. such that byproducts of the reaction are evaporated away into a vacuum exiting the reaction chamber.

Not only does C₂H₂F₂ have a much lower GWP than standard fluorochemical etching gases, it also produces lower CO₂ equivalent emissions from the etching process. The disclosed cryogenic plasma etch method uses C₂H₂F₂ as etching gas to produce apertures, such as channel holes, gate trenches, staircase contacts, capacitor holes, contact holes, contact etch, slit etch, self-aligned contact, self-aligned vias, super vias etc., in silicon-containing films. The resulting apertures may have an aspect ratio ranging from approximately 5:1 to approximately 500:1, preferably from approximately 20:1 to approximately 400:1. The resulting apertures may have a diameter ranging from approximately 0.1 nm to approximately 500 nm; preferably, ranging from approximately 0.1 nm to approximately 500 nm; more preferably being less than 100 nm. The resulting apertures may have an aspect ratio above 1:1, preferably above 5:1, more preferably above 10:1, even more preferably above 20:1. The resulting apertures may have an aspect ratio ranging from 1:1 to 5:1. For example, one of ordinary skill in the art will recognize that a channel hole etch produces apertures in the silicon-containing films having an aspect ratio greater than 50:1.

The disclosed cryogenic plasma etching method is not limited to the above stated experimental conditions in any way, types of plasma etching tool (e.g., capacity coupled or inductively coupled plasma), process conditions (e.g., pressure, power, temperature, duration of process), process gas mixture, combination and proportion of gases in the process gas mixture, gas flow, workpiece and plasma etching chamber itself may be altered for each process and during the process.

In summary, the disclosed cryogenic plasma etching methods provide using C₂H₂F₂ to enhance control of the deposition profile of the polymer film, as well as to etch silicon oxide and silicon nitride or combination thereof with high etch rates and selectivity due to enhanced production of HF in the plasma. Additionally, C₂H₂F₂ have lower GWP compared to commonly used ones (e.g., CF₄, C₄F₈, CH₂F₂), enabling more eco-friendly processes.

### EXAMPLES

A more detailed description of the disclosed methods through examples is provided as follows. However, the disclosed methods is not limited to presented examples in any way and process conditions, process gas mixture, combination and proportion of gases in the gas mixture, workpiece and plasma etching chamber itself may be altered.

In the following Examples, the primary plasma etching source may be a CCP plasma but may also include other sources such as ICP, microwave, ECR, etc. The plasma may be used in a continuous source or as a pulsed plasma of a certain frequency and duty cycle. The temperature of substrate surface may be cooled down or elevated by a cryogenic chiller, or by liquid N₂ supply and heating stage. Additional fluorocarbon gases may be added to slightly tune the etching performance. Additional inert gases may be added such as Kr, Xe, Ne, Ne as well as hydrogen source gases such as H₂, and hydrocarbons. The mask material may include TiN or other metal nitride materials, SiN, Si, carbon materials, or the like. In the following Examples, for comparison purpose, the etching and emission performance of CH₂F₂ and C₄H₂F₆, which are disclosed in US 2023/0127467, are also presented.

### Example 1. Comparison of HF Emissions for C₂H₂F₂, CH₂F₂ and C₄H₂F₆ in O₂ Plasma Process

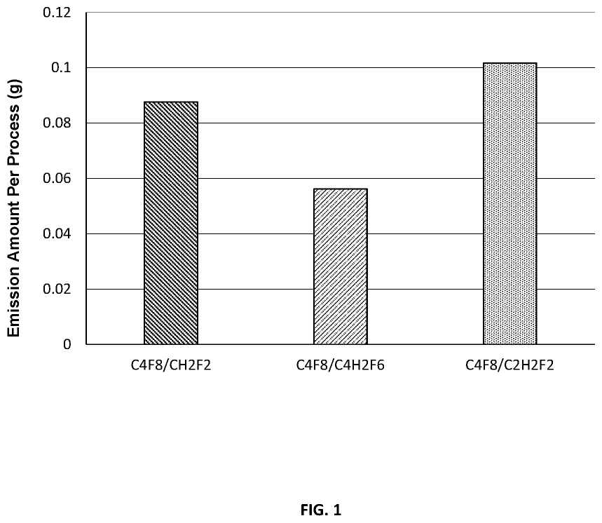

The capability of producing HF species by utilizing C₂H₂F₂ as an etching gas is presented herein. In a 300 mm CCP plasma etch chamber an HF producing gas, C₄F₈, and O₂ along with an inert gas (e.g., argon) were flowed at flow rates described in Table 3 below. The flow rates of the HF producing gases C₂H₂F₂, CH₂F₂ and C₄H₂F₆ were chosen to have similar molar quantities of F into the chamber. The amount of HF produced by the plasma of these gases was measured downstream using FTIR and quantified for each condition. As can be seen in FIG. 1, under these process conditions the amount of HF produced by these gases is C₂H₂F₂>CH₂F₂>C₄H₂F₆. C₂H₂F₂ produces 16% more HF than CH₂F₂ and 81% more than C₄H₂F₆. Therefore, compared to CH₂F₂ and C₄H₂F₆, C₂H₂F₂ produces higher concentrations of HF in the plasma that may be advantageous for cryogenic etching applications.

TABLE 3

| Etch | | C₄F₈/CH₂F₂ | C₄F₈/C₄H₂F₆ | C₄F₈/C₂H₂F₂ |
|---|---|---|---|---|
| RF Source [W] | | 950/200 | 950/200 | 950/200 |
| RF Bias [W] | | 6000/200 | 6000/200 | 6000/200 |
| DC [%] | | 70 | 70 | 70 |
| Frequency [Hz] | | 500 | 500 | 500 |
| Time [s] | | 120 | 120 | 120 |
| Pressure [mTorr] | | 15 | 15 | 15 |
| Wafer T [° C.] | | 20 | 20 | 20 |
| Gas | C₄F₈ | 4 | 4 | 4 |
| Flow | CH₂F₂ | 50 | 0 | 0 |
| Rate | C₄H₂F₆ | 0 | 16.5 | 0 |
| [sccm] | C₂H₂F₂ | 0 | 0 | 50 |
| | O₂ | 21 | 20 | 32 |
| | Ar | 150 | 150 | 150 |

### Example 2. Comparison of CH₂F₂ and C₂H₂F₂ HF Emissions in N₂ Plasma Process

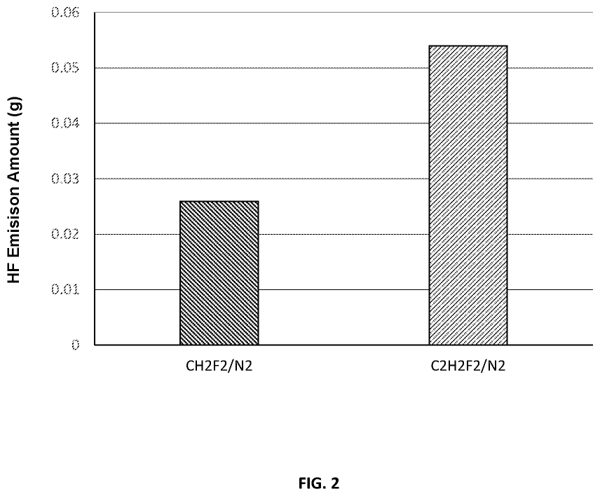

In a 300 mm CCP plasma etch chamber 2 different gases (CH₂F₂ and C₂H₂F₂) were flowed into the etch chamber in different experiments to compare their performance. The experiment conditions are shown in Table 4 below. Each was flowed at a flow rate of 20 sccm with a flow rate of 40 sccm of N₂ and 150 sccm of argon. No oxygen was used in this experiment. Under these conditions as shown in FIG. 2 it was observed that the resulting HF produced in the exhaust of the etch chamber using FTIR was over 2 times higher for C₂H₂F₂ than CH₂F₂, which shows the benefit of C₂H₂F₂. One explanation of this result is that N₂ in the plasma may produce a number of different radical species that change the fragmentation of the fluorocarbon gases. According to Yao et al., (Nanomaterials 2022, 12(21), 3798) nitrogen plasma has more atoms and molecules of metastable and vibrational states, which have higher energy than oxygen plasma. Therefore, in nitrogen plasma, there are more paths for dissociating various species in the plasma. Even though each molecule only has two Hs and two Fs, C₂H₂F₂ produces much more HF species in a N₂ plasma environment, as shown in FIG. 2.

TABLE 4

| | | |
|---|---|---|
| Etch | CH₂F₂/N₂ | C₂H₂F₂/N₂ |

| RF Source [W] | | | 950/200 | 950/200 |
|---|---|---|---|---|
| RF Bias [W] | | | 6000/200 | 6000/200 |
| DC % | | | 70 | 70 |
| Frequency [Hz] | | | 500 | 500 |
| Time [s] | | | 180 | 180 |
| Pressure [mTorr] | | | 15 | 15 |
| Wafer T [° C.] | | | 20 | 20 |
| | Gas | CH₂F₂ | 20 | 0 |
| | Flow | C₂H₂F₂ | 0 | 20 |
| | Rate | N₂ | 40 | 40 |
| | [sccm] | O₂ | 0 | 0 |
| | | Ar | 150 | 150 |

### Example 3. Etch Rates of CH₂F₂ and C₂H₂F₂

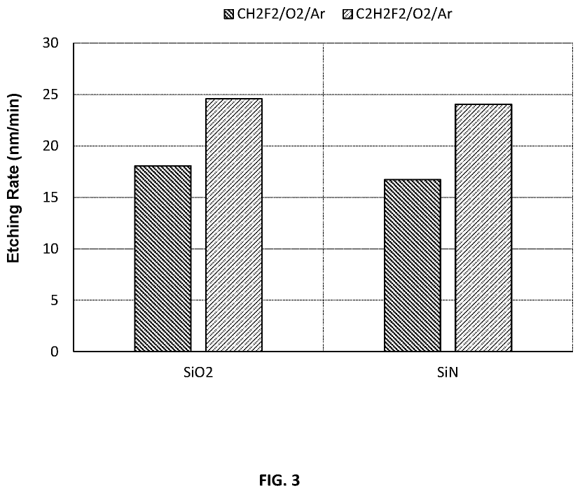

C₂H₂F₂ and CH₂F₂ were each flowed into a 300 mm CCP plasma etch chamber along with O₂ and argon with source power of 950/200 W and Bias power of 6000/200 W and a duty cycle of 70% with experiment conditions as described in Table 5. The etching rates of SiO and SiN wafers were measured and shown in FIG. 3. The etching rates of C₂H₂F₂ for SiO and SiN is higher than those of CH₂F₂. This shows that C₂H₂F₂ provides enhanced SiO and SiN etching rates even though both molecules deliver the same number of F atoms per molecule. The possible reason is that C₂H₂F₂ may more effectively deliver fluorine radical for etching.

TABLE 5

| | | |
|---|---|---|
| Etch | CH₂F₂/O₂ | C₂H₂F₂/O₂ |

| RF Source [W] | | | 950/200 | 950/200 |
|---|---|---|---|---|
| RF Bias [W] | | | 6000/200 | 6000/200 |
| DC % | | | 70 | 70 |
| Frequency (Hz] | | | 500 | 500 |
| Time [s] | | | 180 | 180 |
| Pressure [mTorr] | | | 15 | 15 |
| Wafer T [° C.] | | | 60 | 60 |
| | Gas | CH₂F₂ | 20 | 0 |
| | Flow | C₂H₂F₂ | 0 | 20 |
| | Rate | N₂ | 0 | 0 |
| | [sccm] | O₂ | 40 | 40 |
| | | Ar | 150 | 150 |

### Example 4. Deposition Rates of CH₂F₂ and C₂H₂F₂

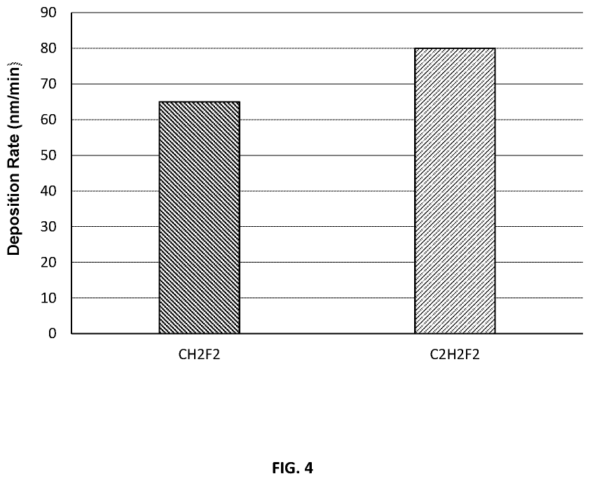

In a 200 mm CCP plasma etch chamber, deposition rates of C₂H₂F₂ and CH₂F₂ were measured. Each hydrofluorocarbon was separately flowed into the chamber at 15 sccm with an argon flow rate of 250 sccm. The source power was 750 W and there was no bias power. The pressure of the chamber was 30 mTorr. The deposition rate of CH₂F₂ was 65 nm/min and the deposition rate of C₂H₂F₂ was 80 nm/min which is 23% higher than that of CH₂F₂. The enhanced polymer generation of C₂H₂F₂ may be beneficial for sidewall protection during the cryogenic etching process. The etching rates of SiO and SiN wafers were measured and shown in FIG. 4.

### Example 5. HF Emissions of CH₂F₂, C₄H₂Fᵣ and C₂H₂F₂

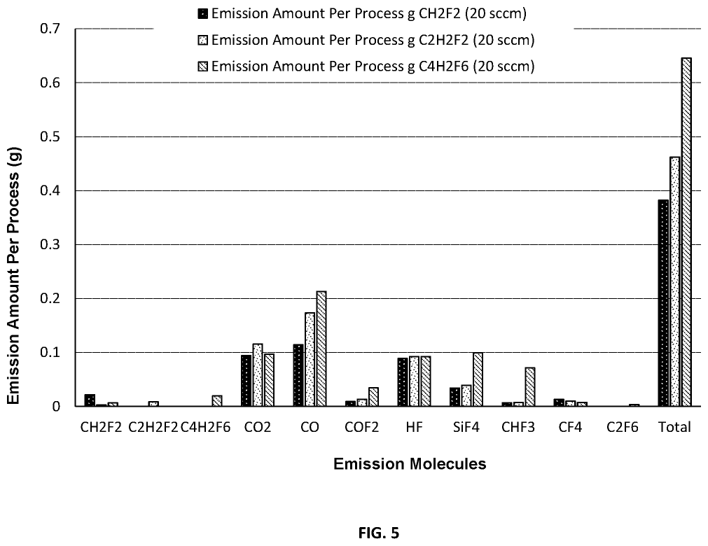

In a 300 mm CCP plasma etch chamber, the HF emissions were measured using an FTIR downstream of the etching chamber for three different etching gases, C₂H₂F₂, CH₂F₂, and C₄H₂F₆, presented herein. The three different etching gases were flowed into the etch chamber in 3 separate experiments, each with a flow rate of 20 sccm, with a source power of 950 W and a bias power of 6000 W including plasma pulsing and duty cycle of 70%. The pressure of the chamber was 15 mTorr. O₂ was flowed at a flow rate of 40 sccm and argon at 150 sccm. The time was 180 s and wafer temperature was 60° C. As shown in Table 6, the amount of HF generated in the exhaust of the etching chamber was very similar between the three gases under these conditions. However, when comparing C₂H₂F₂ to C₄H₂F₆, C₄H₂F₆ has 3 times the amount of F inputting into the chamber plasma chemistry. The trend of HF generated per F atom input into the process is C₂H₂F₂>CH₂F₂>>C₄H₂F₆. Thus, C₂H₂F₂ creates more HF per number of F in the plasma. FIG. 5 shows the more detailed composition of the emissions from the etching process for each of the three gases. It is observed that the emissions of the C₂H₂F₂ unbroken down molecule is less than C₄H₂F₆ indicating that C₂H₂F₂ more effectively breaks down in the plasma. Also, there is much less high GWP byproducts produced in the C₂H₂F₂ plasma as compared to C₄H₂F₆ and CH₂F₂. For example C₂H₂F₂ makes less CF₄ and CH₂F₂ byproducts compared to CH₂F₂. C₂H₂F₂ also makes less CHF₃ byproduct as compared to C₄H₂F₆. Each of these byproducts are high GWP (referring to Table 1). Thus C₂H₂F₂ is a gas with a lower GWP than CH₂F₂ and C₄H₂F₆ and it's plasma emission byproducts are lower GWP as compared to CH₂F₂ and C₄H₂F₆.

TABLE 6

| | Amount of HF generated | Amount of HF generated |
|---|---|---|
| Process gases | (grams) | per F input |
| CH₂F₂ | 0.089 | 0.045 |
| C₄H₂F₆ | 0.092 | 0.015 |
| C₂H₂F₂ | 0.092 | 0.046 |

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

What is claimed is:

1. A cryogenic etching method for forming an aperture by selectively etching one or more silicon-containing films in a substrate using a patterned mask layer deposited on top of the one or more silicon-containing films, the method comprising:
mounting the substrate in a reaction chamber;
cooling the substrate to a temperature below approximately 25° C.;
introducing an etching gas C₂H₂F₂ into the reaction chamber;
converting the etching gas to a plasma; and
allowing an etching reaction to proceed between the plasma and the one or more silicon-containing films so that the one or more silicon-containing films are selectively etched versus the patterned mask layer to form the aperture.

2. The method of claim 1, further comprising
adding one or more hydrofluorocarbon or fluorocarbon etching gases to the etching gas C₂H₂F₂, wherein the one or more hydrofluorocarbon or fluorocarbon etching gases are selected from C₄F₆, C₄F₈, C₄H₂F₆, CHF₃, CH₂F₂, CH₃F, CF₄, C₂F₆, C₃F₈, SFr, NF₃, C₂F₄, C₃F₆, C₄F₁₀, C₅F₆, C₆F₆, C₁-C₆ CₓF_{y}H_{z} molecule (x, y, and z are integers), C₂H₅F, C₃H₇F, C₃H₂F₆, C₂HF₅, C₃H₂F₄, or combination thereof.

3. The method of claim 1, further comprising
adding an additive to the etching gas C₂H₂F₂, wherein the additive is selected from H₂, SFr, NF₃, NH₃, Cl₂, BCl₃, BF₃, Br₂, F₂, FNO, FNO₃, HBr, HCl, HI, IF₅, IF₇, HF, B₂H₆, or P-containing gases selected from PF₃, PCl₃, PBr₃, PH₃, POCl₃, PF₅, POF₃, PH₃ or P(R)₃ where R is an alkyl, or fluorinated alkyl groups selected from CF₃.

4. The method of claim 1, further comprising
adding a co-reactant to the etching gas C₂H₂F₂, wherein the co-reactant is selected from O₂, CO, CO₂, NO, NO₂, N₂O, SO₂, H₂S, COS, O₃, CₓO_{y}F_{z} (x, y and z are integers) selected from COF₂, C₂O₂F₂, CₓO_{y}F_{z}Hₘ (x, y, z and m are integers) selected from alcohol, ketone, acidic, ester type molecule selected from CF₃OH, CF₃OCF₃, (CF₃)₂C═O, CF₃COOH, or combinations thereof.

5. The method of claim 1, further comprising
adding an inert gas to the etching gas C₂H₂F₂, wherein the inert gas is selected from Ar, Kr, Xe, Ne, N₂, He or combination thereof.

6. The method of claim 1, wherein the etching gas C₂H₂F₂ is an isomer of C₂H₂F₂ with CAS No.: 75-38-7.

7. The method of claim 1, wherein the etching gas C₂H₂F₂ is an isomer of C₂H₂F₂ with CAS No.: 1630-78-0.

8. The method of claim 1, wherein the etching gas C₂H₂F₂ is an isomer of C₂H₂F₂ with CAS No.: 1630-77-9.

9. The method of claim 1, wherein the etching gas C₂H₂F₂ is an isomer of C₂H₂F₂ with CAS No.: 1691-13-0.

10. The method of claim 1, wherein the temperature of the substrate is below approximately −50° C.

11. The method of claim 1, wherein the temperature of the substrate ranges from approximately −196° C. to approximately 300° C.

12. The method of claim 1, wherein the temperature of the substrate ranges from approximately −196° C. to approximately 60° C.

13. The method of claim 1, wherein the temperature of the substrate ranges from approximately −196° C. to approximately −50° C.

14. The method of claim 1, wherein the aspect ratio of the aperture ranges from 1:1 to 5:1.

15. The method of claim 1, wherein the aspect ratio of the aperture is above 5:1.

16. The method of claim 1, wherein the aspect ratio of the aperture is above 20:1.

17. The method of claim 1, wherein the aspect ratio of the aperture ranges from approximately 5:1 to approximately 500:1.

18. The method of claim 1, wherein the aperture has a diameter ranging from approximately 0.1 nm to approximately 500 nm.

19. The method of claim 1, wherein the aperture has a diameter less than 100 nm.

20. The method of claim 1, wherein after the aperture is formed, the temperature of the substrate is increased to greater than −50° C.
